(19) United States
(12) Patent Application Publication
(10) Pub. No.: US 2025/0316656 A1
(43) Pub. Date: Oct. 9, 2025

(54) STITCH-CHIP ARCHITECTURES WITH MICROINTERCONNECTS FOR CHIPLETS AND RELATED DEVICES

(71) Applicant: Georgia Tech Research Corporation, Atlanta, GA (US)

(72) Inventors: Muhannad S. BAKIR, Atlanta, GA (US); Ting ZHENG, Atlanta, GA (US)

(21) Appl. No.: 18/865,020

(22) PCT Filed: Jun. 23, 2023
(86) PCT No.: PCT/US2023/068964

§ 371 Date: Nov. 12, 2024

Related U.S. Application Data
(60) Provisional application No. 63/354,880, filed on Jun. 23, 2022.

(51) Int. Cl. H01L 25/16; H01L 23/00; H01L 23/66; H05K 1/02

(52) U.S. Cl. CPC H01L 25/16; H01L 23/66; H01L 24/45; H01L 24/48; H05K 1/0203; H05K 1/0215; H01L 2223/6627; H01L 2224/45155; H01L 2224/45184; H01L 2224/48145; H01L 2224/48225; H01L 2924/14215

(57) ABSTRACT

A device includes a substrate; first and second chiplets on the substrate, each of the first and second chiplets having a backside and an opposing frontside, wherein the backside of the first and second chiplets faces the substrate; and at least one stitch-chip having compressible microinterconnects connecting the frontside of the first chiplet to the frontside of the second chiplet opposite the substrate.

### REFERENCE TO PRIORITY APPLICATION

The present application claims priority to U.S. Provisional Application 63/354,880, filed Jun. 23, 2023, the disclosure of which is hereby incorporated herein by reference.

### FIELD OF THE INVENTION

The present invention relates to stitch-chip architectures with microinterconnects for chiplets.

### BACKGROUND OF THE INVENTION

As developments in wireless communication enable new applications due to high data-rate, low latency, and wide bandwidth channels, the performance requirements of such wireless systems are challenging to conventional packaging technologies. In particular, managing off-chip interconnect losses and transitions may become challenging for high-frequency mm-wave systems.

Currently, wire- or ribbon-bonds are typically used to bridge chiplets together and connect them to a substrate or a printed circuit board (PCB). However, such approaches may introduce high parasitic inductance at high frequencies, significant impedance mismatch, and additional radiation losses, which may degrade the electrical performance of the system. To improve the performance, a matching network may be utilized for a relatively narrow bandwidth; however, the matching network may occupy extra area between the chiplets, which may reduce or prevent high-performance, dense milti-chiplet integration.

Heterogeneous integration technologies with ultra low-loss and broadband interconnects that may be compatible with a variety of chiplets, including commercial off-the-shelf (COTS) chiplets, are needed.

### SUMMARY OF THE INVENTION

In some embodiments, a device includes a substrate; first and second chiplets on the substrate, each of the first and second chiplets having a backside and an opposing frontside, wherein the backside of the first and second chiplets faces the substrate; andat least one stitch-chip having compressible microinterconnects connecting the frontside of the first chiplet to the frontside of the second chiplet opposite the substrate.

In some embodiments, a device includes a substrate having a ground plane and a plurality of recesses, each of the plurality of recesses having a bottom surface comprising the ground plane; first and second chiplets each having a backside and an opposing frontside, wherein the first and second chiplets are in respective ones of the plurality of wells and the backsides of each of the first and second chiplets are on the ground plane; at least one stitch-chip having compressible microinterconnects connecting the frontside of the first chiplet to the frontside of the second chiplet.

### BRIEF DESCRIPTION OF THE DRAWINGS

FIG. 1 is a cross-sectional view of a device having stitch-chips connecting chiplets according to some embodiments.

FIG. 2A is a cross-sectional view and a top view of compressible microinterconnects for stitch-chips according to some embodiments.

FIG. 2B is a flowchart of an optimization procedure for designing a stitch-chip according to some embodiments.

FIG. 3 is a top view of a stitch-chip design with the optimized compressible microinterconnects of FIGS. 2A-2B.

FIGS. 4A-4D are cross sectional views illustrating a stitch-chip fabrication process, including a lift-off for a coplanar waveguide (FIG. 4A), a photoresist patterning step (FIG. 4B), a seed layer sputtering process, photoresist molding and compressible microinterconnect molding, and compressible microinterconnect electroplating (FIG. 4C), and compressible microinterconnect releasing (FIG. 4D).

FIGS. 5A-5D are cross sectional views illustrating a testbed substrate fabrication process including etching mask patterning (FIG. 5A), inductive coupled plasma (ICP) etching (FIG. 5B), a plasma-enhanced chemical vapor deposition (PECVD) process (FIG. 5C), and a process to lift off the proving pads.

FIG. 6 is a cross-sectional view of a flip chip assembly of the stitch-chip on the testbed substrate of FIGS. 5A-5D.

FIG. 7A is a graph illustrating the substrate coupling effect on return loss (RL) (y-axis in decibels (DB)) as a function of frequency (x-axis in Gigahertz (GHz)) due to a gap between the stitch-chip and the test bed substrate.

FIG. 7B is a graph illustrating the insertion loss (IL) (y-axis in decibels (DB)) as a function of frequency (x-axis in Gigahertz (GHz)) of the stitch-chip and wire bond.

FIG. 7C is a graph illustrating the return loss (RL) (y-axis in decibels (DB)) as a function of frequency (x-axis in Gigahertz (GHz)) of the stitch-chip and the wire bond.

### DETAILED DESCRIPTION OF EMBODIMENTS

The present invention now will be described more fully with reference to the accompanying drawings, in which preferred embodiments of the invention are shown. This invention may, however, be embodied in many different forms and should not be construed as being limited to the embodiments set forth herein; rather, these embodiments are provided so that this disclosure will be thorough and complete, and will fully convey the scope of the invention to those skilled in the art. Like reference numerals refer to like elements throughout.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer, or section. Thus, a first element, component, region, layer, or section discussed below could be termed a second element, component, region, layer or section without departing from the teachings of the present invention.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprising”, “including”, “having” and variants thereof, when used in this specification, specify the presence of stated features, steps, operations, elements, and/or components, but do not preclude the presence or addition of one or more other features, steps, operations, elements, components, and/or groups thereof. In contrast, the term “consisting of” when used in this specification, specifies the stated features, steps, operations, elements, and/or components, and precludes additional features, steps, operations, elements and/or components.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

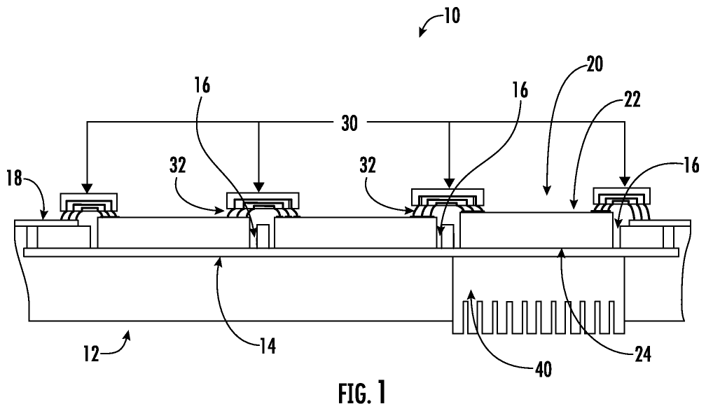

Referring now to FIG. 1, a device 10 is shown including a substrate 12 having a ground structure, such as a ground plane 14, and a plurality of wells 16. Each of the wells 16 has a bottom surface that includes the ground plane 14. Chiplets 20 are positioned in the wells 16. The chiplets 20 include a front side 22 and an opposing back side 24. As illustrated, the chiplets 20 are in respective ones of the wells 16 such that the back sides 24 of each of the chiplets 20 are on the ground plane 14 on the bottom surface of the well. Stitch-chip 30 are provided with mircrointerconnects 32 that connect the front sides 22 of the chiplets. A heat sink 40 connects the ground plane 14 opposite the chiplets 20.

In some embodiments, the stitch-chips 30 are fused-silica stitch-chips and the chiplets may be RF/mm-wave chiplets, including commercial off-the-shelf (COTS), with back side grounding. The substrate 12 may be an organic or inorganic substrate or a printed circuit board. The back sides 24 of the chiplets 20 may be bonded to the common ground plane 14 and the heat sink 40 with a conductive adhesive for increasing heat dissipation. The heat sink 40 may be formed of a thermally conductive material, such as aluminum or copper. The ground plane 14 and transmission line 18 may be formed of an electrically conductive material, such as copper or gold.

The stitch-chips 30 may be used to connect different chiplets 20, such as a low noise amplifier (LNA), power amplifier (PA). The chiplets 20 may optionally be positioned in the wells 16 or recesses of the substrate 12; however, in some embodiments, the wells 16 are omitted. For example, the substrate 12 may be a planer surface with the chiplets 20 on the planar surface. In this configuration, low-loss, low-parasitic and impedance matched interconnects may be designed on the stitch-chips for broad bandwidth applications. Accordingly, matching networks may not be needed to connect different chips, and high-performance, dense, multi-chiplet integration may be achieved. Moreover, chiplets of different heights and with different impedance mismatch may be connected. It should be understood that the stitch-chips 30 may be used to connect two active die or a die and a package. In some embodiments, the stitch-chips may be sued to connect two packages on the substrate 12 or printed circuit board. The stitch-chips 30 may be connected using any suitable method; for example, the stitch-chips 30 having microinterconnects 32 may be physically attached using various methods, such as a UV-curable epoxy.

The compressible microinterconnects 32 may be mechanically compliant off-chip input/outputs (I/Os) and may be utilized to interface the stitch-chips 30 with the chiplets 20. During assembly of the stitch-chips, the compressible microinterconnects 32 may deform elastically between the stitch-chips 30 and the chiplets 20 and may recover to the original profiles when disassembling the stitch-chips. Compressible microinterconnects 32 with a high degree of mechanical compliance may enable the compressible microinterconnects 32 to compensate for any thickness differences between difference between the chiplets 20, for example, when different types of chiplets are used on the same substrate. For example, a power amplifier (PA) is typically thicker than a switch chiplet. Moreover, the mechanical compliance of the compressible microinterconnects 32 may permit potential non-planarity between chiplets 20 on the substrate 12. In addition, the compressible microinterconnects 32 may facilitate the integration of various types of chiplets that may have a coefficient of thermal expansion mismatch such that the relative heights of the chiplets may change over time or as a function of temperature. Accordingly, stitch-chips with different designs may be assembled or disassembled for system performance enhancement due to the reworkability enabled by the compressible microinterconnects 32. The length of the compressible microinterconnects 32 may be 20 to 100 μm or more.

Accordingly, by positioning the stitch-chips 30 on a side of the chiplets 20 opposite the substrate 12, different heights of chiplets may be accommodated on the same substrate.

A microwave network analyzer, Keysight™ N5245A PNA-X (available from Keysight Technologies, Santa Rosa, CA, USA). Cascade Microtech ground-source-ground (G-S-G)|Z| probes are placed on the probing pads of the testbed. Short-open-load-thru (SOLT) calibration is used to move the measurement reference planes to the probe tips.

The stitch-chip includes an RF design of coplanar waveguides with a pitch-transition, and an RF-mechanical co-design of the ground-signal-ground compressible microinterconnects, which are located at the ends of the coplanar waveguides.

The co-design of the coplanar waveguides and the compressible interconnects has been modeled using ANSY Workbench™ simulation integration platform software (available from ANSYS, Inc., Canonsburg, PA, USA) further using HFSS™, Static Structural, and Direct Optimization modules with Multi-Objective Genetic Algorithm (MOGA).

The compressible microinterconnects 32 may be fabricated using nickel tungsten, NiW, which has a Young's modulus of 180 GPa and is coated with electroless Au. Examples of the fabrication of the stitch-chips are found in T. Zheng, P. K. Jo, S. K. Rajan, and M. S. Bakir, “Electrical characterization and benchmarking of polylithic integration using fused-silica stitch-chips with compressible microinterconnects for RF/mm-wave applications,” IEEE Trans. Compon. Packag. Manuf. Technol., vol. 11, no. 11, pp. 1824-1834 Nov. 2021.

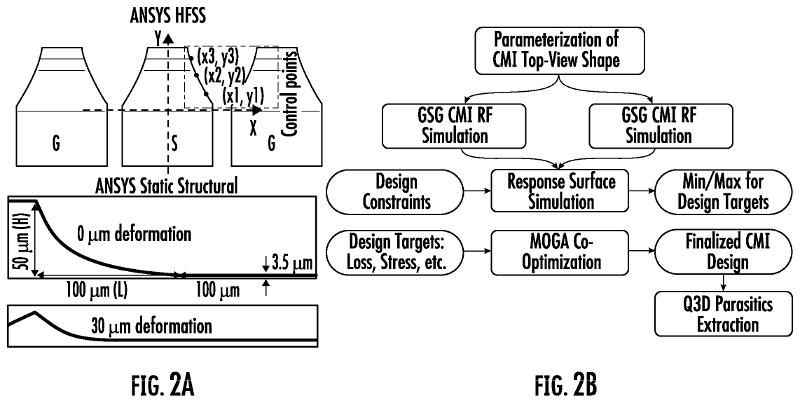

As illustrated in FIG. 2A, the compressible microinterconnects have a curved profile in the Static Structural generated cross-sectional view and its top view generated by HESS is parameterized by three control points that may be co-optimized for reduced return loss (RL) (>10 dB), reduced insertion loss (IL) (<1 dB), and reduced equivalent stress (<1.93 GPa (expected NiW's yield strength)). The curvature of the compressible microinterconnect may be determined by the compressible microinterconnect body height (H) and body length (L) as illustrated in FIG. 2A. An outline of the example optimization process is shown in FIG>2B.

The following Table summarizes an example of compressible microinterconnect RF and mechanical performance. The compressible microinterconnect design may compensate up to 30 μm of non-planarity or height difference between chiplets with its elastic deformation characteristics. Compressible microinterconnects may be formed with acceptable return loss (RL), low insertion loss (IL), and low parasitics, which may reduce the impedance mismatch between the stitch-chips and the chiplets. The compressible microinterconnect design may be combined with coplanar waveguides to form signal channels on stitch-chips with pitch-transition.

TABLE
Optimized Compressible Microinterconnects RF
(65 GHz bandwidth) and Mechanical Performance

| Pitch/deform | Stress | RL | IL | |
|---|---|---|---|---|
| (μm) | (GPa) | (dB) | (dB) | Parasitics |
| 200/30 | <1.9 | >12.2 | <0.4 | <0.7 Ω, 25 |
| | | | | pH, |
| | | | | 21 fF |

A top view of the stitch-chip design with the parameters described above is shown in FIG. 3. Fused-silica is used as a substrate due to its low-loss characteristics, which has a dielectric constant of 3.9, a loss tangent of 0.0002, and a thickness of 500 μm. A coplanar waveguide with a length of 500 μm and a pitch transition from 200 μm to 300 μm is designed to approximate or compensate for potential pitch or height differences between the chiplet pads and package pads. The width of the center signal conductor and the gap between the signal conductor and adjacent reference conductors are optimized to achieve approximately 50Ω for the stitch-chip channel. The coplanar waveguide is modeled and fabricated using 300 nm-thick Cu with 100 nm-thick Au. The compressible microinterconnects are positioned at the ends of the coplanar waveguides as off-chip input/outputs (I/Os). Multiple compressible microinterconnects are placed on the refence conductors on the 300 μm pitch side to reduce inductance.

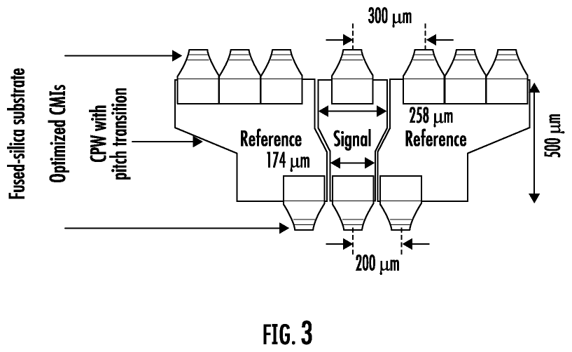

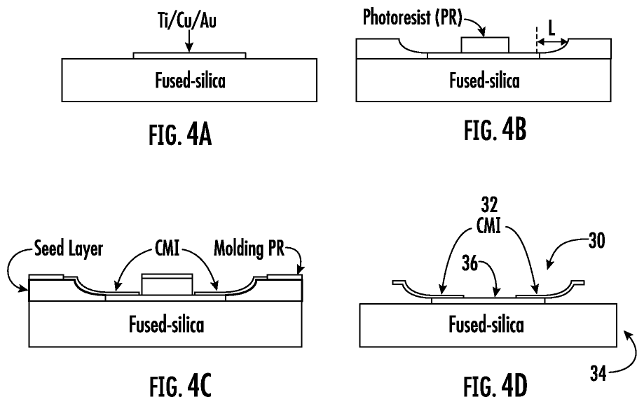

The stitch-chip fabrication is illustrated in FIGS. 4A-4D. A lift off photolithography is performed on the stitch-chip fused-silica substrate to provide a thin film of Ti/Cu/Au coplanar waveguide (FIG. 4A). Next, a photoresist is coated and patterned to have a curved sidewall (FIG. 4B). The compressible microinterconnect curvature is controlled by the photoresist thickness and the length is defined by a hard mask as shown in FIG. 4B. A Ti/Cu/Ti seed layer is sputtered and another photoresist layer is patterned as an electroplating mold in FIG. 4C. After NiW electroplating, the compressible microinterconnects are released by removing the seed and photoresist layers and an Au plating is performed (FIG. 4D).

As shown in FIG. 4D, the stitch-chip 30 includes the compressible microinterconnects 32 on a coplanar waveguide 36 on a fused-silica substrate 34. Although the coplanar waveguide 36 is described as a thin film Ti/Cu/Au coplanar waveguide, other configurations of waveguides may be used, including a microstrip electrical transmission line, which may include a conductor that is separated from a ground plane by a dielectric layer substrate. A microstrip may be used to convey microwave-frequency signals. The compressible microinterconnect is described as formed of NiW that is plated with Au and the substrate is described as a fused-silica substrates; however, it should be understood that other interconnects may be used. Moreover, although some embodiments are described herein with respect to compressible microinterconnects, it should be understood that solder bumps and microbumps may be used as interconnects.

Moreover, various dimensions may be used. For example, the substrate 34 may have a thickness from 100 μm to 500 μm and a length from 0.15 mm to 2 mm. The coplanar waveguide may have thickness from 300 nm to 5 μm and a length from 0.1 mm to 1 mm.

The dimensions of the compressible microinterconnects 32 may be from 200 μm pitch to 30 μm pitch. The coplanar waveguide may have multiple pitch transition designs. For example, 170 μm to 300 μm or more and 150 μm to 300 μm or more depending on manufacturing limits and chiplets' pad design.

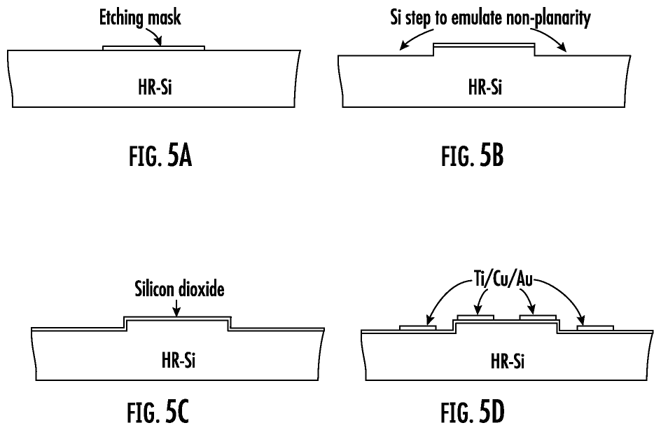

The stitch-chip's performance is evaluated with a testbed substrate with intentional non-polarity as illustrated in FIGS. 5A-5D. High resistivity silicon (Si>10K Ω-cm and a thickness of 300 μm) is used as the substrate. A photoresist mask is patterned followed by an inductive coupled plasma (ICP) etching (FIGS. 5A-5B). The etch creates steps or recesses with a depth of 16.7 μm to approximate or emulate a non-planar package of height differences between chiplets. Next, a 1 μm thick silicon dioxide layer is deposited using plasma-enhanced chemical vapor deposition (FIG. 5C), and probing pads are deposited using lift-off (FIG. 5D).

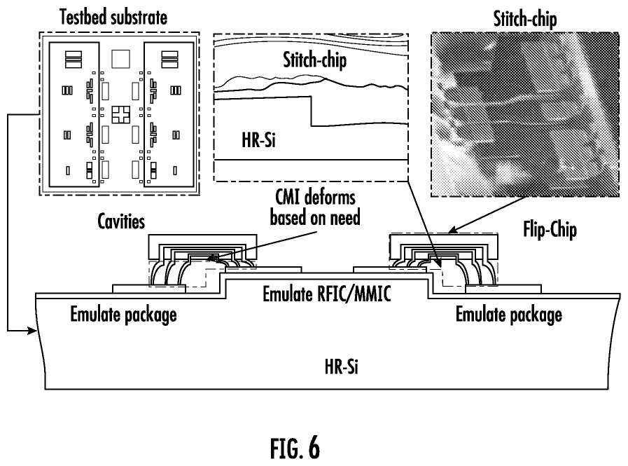

As illustrated in FIG. 6, the flip-chip assembly is completed for the fabricated stitch-chip and the testbed substrate, which are held together with epoxy at the edges of the stitch-chip for demonstration and testing purposes. Due to the recesses on the testbed substrate to emulate the non-planarity, the compressible microinterconnects deform locally and provide robust electrical interfacing during assembly.

A micronetwork analyzer, Keysight N5245A PNA-X, from Keysight Technologies, Inc. (Santa Rose, CA, USA) was used to perform measurements up to 50 GHz. Cascade Microtech G-S-G|Z| probes were placed on the probing pads of the testbed. Short-open-load-thru (SOLT) calibration was used to move the measurement reference planes to the probe tips.

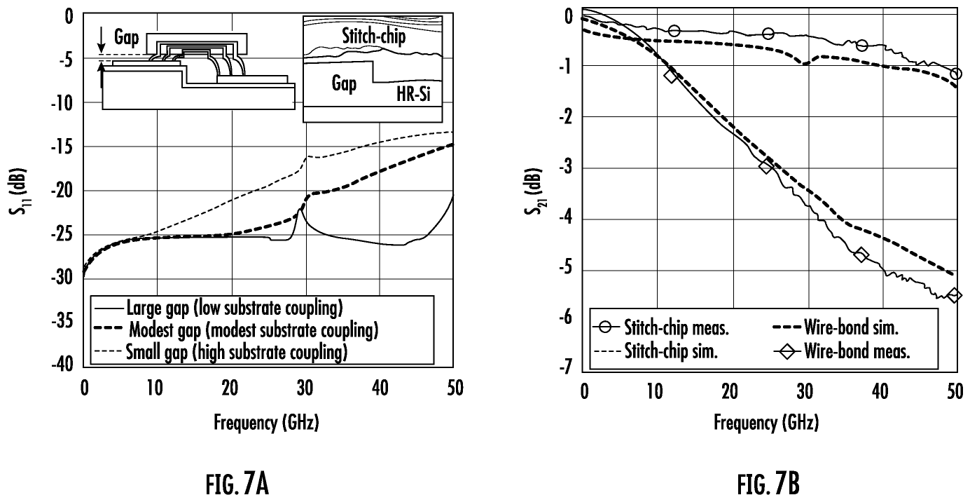

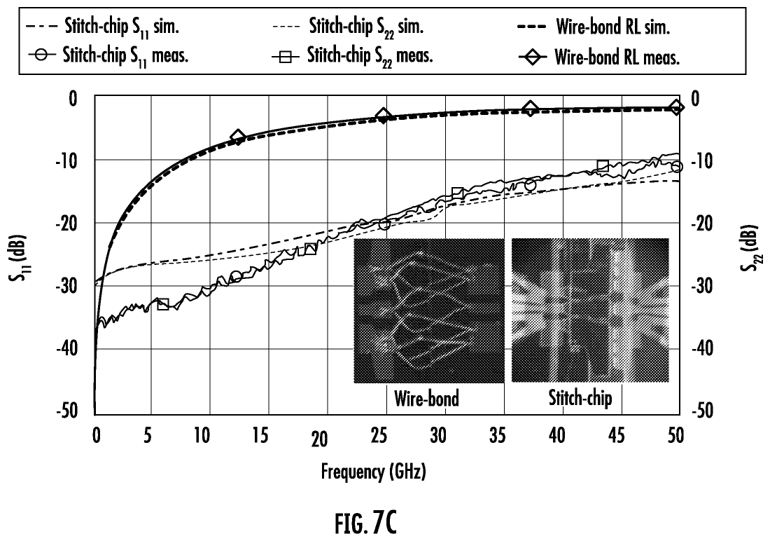

The return loss (RL) degradation due to substrate coupling for the assembled stitch-chip coupling was quantified by the gap between the stitch-chip and the testbed substrate. Three cases were studied: 1) low coupling/large gap (28 μm), 2) modest coupling/gap (13 μm), and 3) high coupling/small gap (8 μm). A large capacitive coupling between the stitch-chip and the testbed substrate can be induced in the small gap case, which causes stitch-chip channel's impedance mismatch and RL degradation (FIG. 7A).

The S-parameters of the assembled stitch-chip and the wire-bond testbed using the same substrate are measured for benchmarking. The wire-bond testbed is prepared by a gold (Au) wedge bonder (1 mil wire diameter), as shown in the schematic of FIG. 7c. The wire-bonds have approximately 1 mm length. Multiple wire-bonds are formed on the reference conductors to reduce inductance. In FIG. 7, the measurements of the stitch-chip and wire-bond testbeds compare well to their simulations. Note that process variation and potential assembly issues, such as flip-chip misalignment, are measured and used to adjust the stitch-chip simulations.

The stitch-chips exhibit superior RF/mm-wave performance compared to conventional wire-bonds. In FIG. 7B, the stitch-chips provide less than 1 dB IL across 50 GHz, which represents a 4.2 dB improvement relative to the testbed using wire-bonds. As shown in FIG. 7C, while the wire-bonds show extreme RL degradation (1.8 dB) up to 50 GHz due to their relatively high parasitic inductance, the stitch-chips demonstrate better than 10 dB RL across the same frequency band. Note that the stitch-chips achieve such broadband lower RL without any impedance matching network that may be required for improving wire-bond's return loss. The impedance matching network may also consume large package area and only operate for a narrow band. The stitch-chip's performance can be improved further by easily designing and fabricating shorter and thicker channels on lower-loss substrates.

Accordingly, fused-silica stitch-chip technology may be used for embedded RF/mm-wave chiplets. The stitch-chip channels demonstrate a high tolerance to substrate coupling with acceptable RL (>10 dB). For 500 μm long stitch-chip channels, >10 dB RL and <1 dB IL are measured across 50 GHz, which correlate well with simulations and demonstrate superior RF/mm-wave performance to commonly used wire-bonds.

Although the flip-chip assembly is described herein with respect to a testbed substrate, it should be understood that various types of chiplets may be connected using the stitch-chips described herein. Suitable types of chiplets include III-V mm-wave chiplet (low noise amplifier, power amplifier, etc.) and Si/SiGe chiplet. Suitable substrates and PCBs include inorganic substrates (Si, glass, etc.) and any PCBs made of high-frequency laminates.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed is:

1. A device comprising:
a substrate;
first and second chiplets on the substrate, each of the first and second chiplets having a backside and an opposing frontside, wherein the backside of the first and second chiplets faces the substrate; and
at least one stitch-chip having interconnects connecting the frontside of the first chiplet to the frontside of the second chiplet opposite the substrate.

2. The device of claim 1, wherein the interconnects comprise compressible microinterconnects.

3. The device of claim 2, wherein the substrate has a ground structure.

4. The device of claim 3, wherein the ground structure comprises a ground plane in the substrate.

5. The device of claim 4, wherein the first and second chiplets are electrically connected to the ground plane.

6. The device of claim 5, wherein the backsides of each of the first and second chiplets are on the ground plane.

7. The device of claim 6, wherein the substrate comprises a plurality of recesses, wherein each of the first and second chiplets are in respective ones of the plurality of recesses and the ground plane extends along a bottom surface of the plurality of recesses to thereby contact the backsides of the first and second chiplets.

8. The device of claim 7, further comprising a heat sink structure on the ground plane opposite the first and second chiplets.

9. The device of claim 2, wherein the first and second chiplets are selected from the group consisting of low noise amplifiers, power amplifiers, variable gain amplifiers and switches, and the first chiplet is different from the second chiplet.

10. The device of claim 1, wherein the substrate comprises a printed circuit board.

11. The device of claim 2, wherein the substrate comprises silicon.

12. The device of claim 2, wherein the stitch-chip comprises a fused-silica substrate, a coplanar waveguide on the fused-silica substrate, and the compressible microinterconnects on the coplanar waveguide.

13. The device of claim 12, wherein the coplanar waveguide comprises Ti/Cu/Au.

14. The device of claim 12, wherein the compressible microinterconnects comprise NiW.

15. The device of claim 1, wherein the first chiplet has a height that is different from the second chiplet.

16. A device comprising:
a substrate having a ground plane and a plurality of recesses, each of the plurality of recesses having a bottom surface comprising the ground plane;
first and second chiplets each having a backside and an opposing frontside, wherein the first and second chiplets are in respective ones of the plurality of recesses and the backsides of each of the first and second chiplets are on the ground plane; and
at least one stitch-chip having compressible microinterconnects connecting the frontside of the first chiplet to the frontside of the second chiplet.

17. The device of claim 16, further comprising a heat sink structure on the ground plane opposite the first and second chiplets.

18. The device of claim 16, wherein the first and second chiplets are selected from the group consisting of low noise amplifiers, power amplifiers, variable gain amplifiers and switches, and the first chiplet is different from the second chiplet.

19. The device of claim 16, wherein the substrate comprises a printed circuit board.

20. The device of claim 16, wherein the substrate comprises silicon.

21. The device of claim 16, wherein the stitch-chip comprises a fused-silica substrate, a coplanar waveguide on the fused-silica substrate, and the compressible microinterconnects on the coplanar waveguide.

22. The device of claim 21, wherein the coplanar waveguide comprises Ti/Cu/Au.

23. The device of claim 21, wherein the compressible microinterconnects comprise NiW.

24. The device of claim 16, wherein the first chiplet has a height that is different from the second chiplet.
